(19) United States
(12) Patent Application Publication
(10) Pub. No.: US 2025/0298927 A1
(43) Pub. Date: Sep. 25, 2025

(54) STRUCTURAL AND MERCHANDISING PLAN GENERATION FOR STORES

(71) Applicant: TARGET BRANDS, INC., Minneapolis, MN (US)

(72) Inventors: Gopikrishna CHAGANTI, Nagavara (IN); Kirti KESAVARAPU, Minneapolis, MN (US); Kiran KUMAR, Nagavara (IN); Mayilavan MANICKAM, Nagavara (IN); Jestin MATHEW, Nagavara (IN); Chandan KUMAR, Nagavara (IN); Sumit KUMAR, Nagavara (IN); Pat HATHAWAY, Minneapolis, MN (US); Srinivasa MALLELA, Nagavara (IN)

(21) Appl. No.: 18/613,967

(22) Filed: Mar. 22, 2024

(51) Int. Cl. G06F 30/12; G06F 30/13

(52) U.S. Cl. CPC G06F 30/12; G06F 30/13

(57) ABSTRACT

In one embodiment, a computer implemented method for merchandising a store is disclosed. The method may include, generating by a processing element a data object representation of the store from a digital model of the store, rendering by the processing element a structural plan of the store from the data object representation of the store, receiving by the processing element a merchandising placement specifying a placement of a first merchandising category at a first position within the structural plan, generating by the processing element a merchandising plane including the first merchandising category position at the first position, wherein the first position is related to a location in the store, and outputting to a display the merchandising plan.

### BACKGROUND

Retail merchandising involves the strategic product placement of goods in retail stores and plays an important role in the success of the business. Merchandising plans, which provide a framework of how merchandise is staged in a store, are often manually created and validated. Current methods for creating a merchandising plan often require manually creating a representation of a store's layout through compiling and interpreting one or more engineering plans for a store. For example, an administrator creating a merchandising plan must manually set the size and position of fixtures in the store layout and determine whether certain categories of merchandise can fit at certain locations within the store. Additionally, even after creation, users must manually place merchandise in the merchandising plan. As each store may require a large plurality of merchandising decisions, such methods are time and resource intensive and prone to error, especially where there are multiple stores that require merchandising.

Furthermore, floor plans in a store are often changing due to store remodeling or updating the position of fixtures within the store. These changes may be permanent placements or temporary placements to reflect seasonal merchandising placements. Current methods for creating merchandising plans do not account for such changes, such that a created plan may not be feasible when being executed by the store employees and the manual process must begin again. In short, current merchandising processes are manual, inefficient, and require multiple iterations to ensure accuracy.

### BRIEF SUMMARY

In one embodiment, a computer implemented method for merchandising a store is disclosed. The method may include, generating by a processing element a data object representation of the store from a digital model of the store, rendering by the processing element a structural plan of the store from the data object representation of the store, receiving by the processing element a merchandising placement specifying a placement of a first merchandising category at a first position within the structural plan, generating by the processing element a merchandising plane including the first merchandising category position at the first position, wherein the first position is related to a location in the store, and outputting to a display the merchandising plan.

In another example, a method for updating a merchandising plan for a store is disclosed. The method includes evaluating a merchandising plan relative to a digital model of the store, generating an updated day object representation of the store from the digital model, rendering an updated structural plan of the store from the updated data object representation of the store, generating a notification regarding the updated store layout, receiving a merchandising placement specifying a placement of a first merchandising category at a first position within the updated structural plan, evaluating the first position placement relative to the updated structural plan and merchandising properties. If the first position is valid in relation to the store layout and merchandising properties, generating an updated merchandising plan including the first category in the first position, where the first position is related to a location in the store, and if the first position is not valid in relation to the store layout and merchandising properties, generating a notification.

In yet another embodiment, a merchandising system is disclosed. The system includes a store data storage comprising one or more structural plans and merchandising properties and a processing configured to generate merchandising plans. The processor is configured to generate a data object representation of the store from a digital model of the store, render a structural plan of the store form the data object representation of the store, receive a merchandising placement specifying a placement of a first merchandising category at a first position within the structural plan and generate a merchandising plane including the first merchandising category positioned at the first position, where the first position is related to a location of the store, and output to a display the merchandising plan.

### BRIEF DESCRIPTION OF THE DRAWINGS

The description will be more fully understood with reference to the following figures in which components are not drawn to scale, which are presented as various examples of the present disclosure and should not be construed as a complete recitation of the scope of the disclosure, characterized in that:

FIG. 1 illustrates an example system including user devices in communication with a merchandising module.

FIG. 2 shows an example digital model and corresponding data object format of a store.

FIG. 3 shows an example user interface of the merchandising module.

FIG. 4 is a flow diagram of example operations for generating a merchandising plan.

FIG. 5 is a flow diagram of example operations for updating the merchandising plan.

FIG. 6 illustrates a schematic diagram of an example computer system implementing various embodiments.

### DETAILED DESCRIPTION

The present disclosure includes a system to automatically and digitally generate structural plans and merchandising plans for stores. The system may translate a digital model of a store floor plan (e.g., an engineering plan or computer aided design model (CAD)) into a structural plan, where the structural plan includes a representation of the structural and architectural features of the store or building that are relevant to merchandising. The system generates a user interface to present the structural plan to users for efficient merchandising decisions and placement. The system may evaluate merchandising placements relative to the store properties (e.g., fixtures and architectural features within the store). The system generates a merchandising plan based on the validated merchandising placements.

Further, in the event that the store floor plan changes or to accommodate seasonal merchandising placements, the system can generate an updated structural plan, automatically and create notifications to receive updated merchandising placements based on the same. Conventional techniques would require a manual updating process (if any) as changes to structural plans were implemented at the structural level, whereas the current system will automatically identify that there has been a structural change and propagate changes and push notifications to update merchandising placements accordingly.

The merchandising module may be accessible by existing operator systems and applications (e.g., computer systems) such that the system may easily scale for personal or commercial use. The system may function as a standalone system or be integrated statically or dynamically into existing software and systems. For example, various modules may be embedded in a website or implemented as a module within a mobile application or software system. Additionally, the module may generate merchandising plans based on digital models of stores of different types and formats.

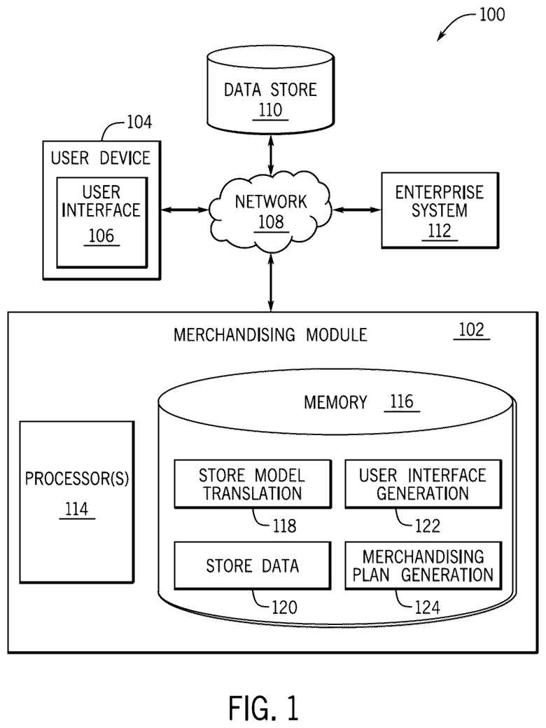

Various embodiments of the present disclosure will be explained below in detail with reference to the accompanying drawings. Other embodiments may be utilized, and structural, logical, and electrical changes may be made without departing from the scope of the present disclosure. Turning now to the drawings, FIG. 1 illustrates an example system including various user devices 104, data stores 110, and enterprise systems 112 in communication with a merchandising module 102, where the merchandising module 102 generates store layouts and merchandising plans. The merchandising module is accessible by users through a user interface 106 on user device 104, e.g., through a website or mobile application.

The merchandising module 102 may be implemented by or at a computing device or combinations of computing resources in various embodiments. In various examples, the merchandising module 102 may be implemented by one or more servers, cloud computing resources, and/or other computing devices. The merchandising module 102 may, for example, be incorporated as a module within a mobile application, software application, or a website presented through a web browser (e.g., at a laptop or desktop computer), and the like.

In some examples, the user device 104 may be a device utilized by an end user, such as an employee, contractor, or other person that is interacting with the merchandising module 102. For example, user device 104 may be a mobile device or other computing device used by an administrator to access the merchandising module 102.

In various implementations, the user device 104 and/or additional user devices may be implemented using any number of computing devices including, but not limited to, a computer, a laptop, tablet, mobile phone, smart phone, wearable device (e.g., AR/VR headset, smart watch, smart glasses, or the like), smart speaker, vehicle (e.g., automobile), or appliance. Generally, the user devices may include one or more processors, such as a central processing unit (CPU) and/or graphics processing unit (GPU). The user devices may perform operations by executing executable instructions (e.g., software) using the processor(s). Though one user device 104 is shown in FIG. 1, any number of user devices may be in communication with the merchandising module 102, in various examples.

The network 108 may be implemented using one or more of various systems and protocols for communications between computing devices. In various embodiments, the network 108 or various portions of the network 108 may be implemented using the Internet, a local area network (LAN), a wide area network (WAN), and/or other networks. In addition to traditional data networking protocols, in some embodiments, data may be communicated according to protocols and/or standards including near field communication (NFC), Bluetooth, cellular connections, and the like.

In various implementations, the merchandising module 102 may be in communication with a data store 110. Data store 110 may include memory storage for information relevant to the merchandising of stores. For example, data store 110 may store the floor plans of retail stores available for merchandising and/or merchandising properties of the retail stores. In other examples, the data store 110 is a structural database that includes the engineering and/or architectural plans for the stores. The data store 110 may store data in various formats and types, e.g., digital models such as engineering drawings and CAD models, and/or data object representations such as JSON objects and coordinate information, and the like. The data store 110 may be distributed across various physical devices or storage systems. Though one data store 110 is shown in FIG. 1, any number of data stores 110 may be in communication with the merchandising module 102, in various examples.

In various implementations, the merchandising module 102 may be in communication with an enterprise system 112. In some examples, the merchandising module 102 may be utilized within the enterprise system 112. For example, the merchandising module 102 may interface with an enterprise system 112 to provide merchandising services as a part of the enterprise system 112. In other examples, the enterprise system 112 may link to or communicate with the merchandising module 102. Though one enterprise system 112 is shown in FIG. 1, any number of enterprise systems 112 may be in communication with the merchandising module 102, in various examples.

Although not shown in FIG. 1, the merchandising module 102 may also be in communication with other systems or components. For example, the merchandising module 102 may be in communication with digital modeling and design systems where a digital model of a retail store may be created and directly communicated to the merchandising module 102.

FIG. 1 additionally illustrates a schematic diagram of an example merchandising module 102, in accordance to various examples provided herein. In various implementations, the merchandising module 102 may include or utilize one or more hosts or combinations of compute resources, which may be located, for example, at one or more servers, cloud computing platforms, computing clusters, and the like. Generally, the merchandising module 102 is implemented by compute resources including hardware for memory 116 and one or more processors 114. For example, the merchandising module 102 may utilize or include one or more processors, such as a CPU, GPU, and/or programmable or configurable logic. In some embodiments, various components of the merchandising module 102 may be distributed across various computing resources, such that components of the merchandising module 102 may communicate with one another through the network 108 or using other communications protocols. For example, in some embodiments, the merchandising module 102 may be implemented as a serverless service, where computing resources for various components of the merchandising module 102 may be located across various computing environments (e.g., cloud platforms) and may be reallocated dynamically and/or automatically according to, for example, resource usage of the merchandising module 102. In various implementations, the merchandising module 102 may be implemented using organizational processing constructs such as functions implemented by worker elements allocated with compute resources, containers, virtual machines, and the like.

The memory 116 may include instructions for various functions of the merchandising module 102 which, when executed by processor 114, perform various functions of the merchandising module 102. The memory 116 may further store data and/or instructions for retrieving data used by the merchandising module 102. Similar to the processor 114, memory resources utilized by the merchandising module 102 may be distributed across various physical computing devices. In some examples, memory 116 may access instructions and/or data from other devices or locations, and such instructions and/or data may be read into memory 116 to implement the merchandising module 102.

The memory 116 may include or access various types of data or instructions used by the merchandising module 102. While such data and instructions are shown in FIG. 1 as being stored at the memory 116, in some examples, the data and instructions may be stored at other memory resources of the merchandising module 102 and/or at locations remote from the merchandising module 102, such as various databases or data stores or data store 110. In such examples, the memory 116 of the merchandising module 102 may include instructions for accessing such data and instructions from remote locations, including, for example, the locations of the data and/or specific queries used to retrieve data for use by the merchandising module 102. Such data and instructions may include store model translation 118, store data 120, user interface generation 122, and merchandising plan generation 124, in various examples.

In various examples, the memory 116 may include instructions for store model translation 118. Such instructions for store model translation 118 may, when executed by the processor 114, create a translated store model, where the translated store model contains one or more data objects including objects that are representative of the different structural and/or architectural features of the store relevant to merchandising. For example, store model translation 118 may receive a digital model of the floor plan of a retail store, such as a CAD model, where the model includes the size and position of fixtures in the store. Store model translation 118 may then translate the digital model into a data object format, such as JSON objects, where data objects represent merchandising fixtures within the store and correspond to fixtures presented in the digital model. For example, merchandising fixtures may include sections of fixtures where merchandise may be placed, structural supports where merchandise may not be placed, and other merchandising features of the store. In some examples, the data object representation of merchandising fixtures includes structural features, dimensions, position, and other properties relevant for merchandising. For example, the data object may include Cartesian coordinates of the location of the fixture within the store, the size dimensions of the fixture, and/or the capacity dimensions for merchandise placement within the fixture. In some examples, the fixture properties include whether merchandise can be placed on the fixture and whether there are any restrictions to merchandise placement for the fixture. For example, sections of fixtures representing columns or building supports may not allow for merchandise placement, while sections of fixtures representing refrigerated fixtures may allow for merchandise placement with temperature restrictions, where merchandising categories placed on the refrigerated fixtures are required to comply with temperature constraints. Store model translation 118 may generate a 2D translated store model from a 3D digital model, where the translated store model includes only 2D data representations of the 3D digital model.

In some examples, after the translated store model for a store has been generated, store model translation 118 may receive an updated digital model which reflect changes in the floor plan of the store. Store model translation 118 may then update the existing corresponding data objects to reflect the changes to the store. For example, if store model translation 118 received an updated digital model which added a fixture and changed the location of another fixture in the store layout, store model translation 118 may add a new data object to the translated store model to reflect the new fixture and may update the positional coordinates of the data object corresponding to the moved fixture.

In various examples, the memory 116 may include store data 120, which may include merchandising categories and properties for corresponding retails stores. In some examples, store data 120 includes categories of merchandise available for placement in individual stores. Certain categories may not be available for placement in all stores. For example, the merchandising category of “chocolates” may be available in some stores and excluded from availability in other stores. In some examples, store data 120 includes merchandising properties of individual stores. Merchandising properties may include the number of fixtures in the store, the total capacity for merchandise placement in the store, the size and location of fixtures in the store, the size and properties of merchandise, and any other such properties that relate to store merchandising. In some examples, the data objects generated by store model translation 118 may be stored in store data 120.

In various examples, the memory 116 may include instructions for user interface generation 122. Instructions for user interface generation 122 may, when executed by processor 114, generate the user interface 106 that is configured to display a store layout to a user, receive merchandising placements from the user, and notify the user of inadequate placements and/or updates in the floor plan. In some examples, the user interface generation 122 may utilize the translated store model generated by store model translation 118 to create and display a structural plan of the store. The structural plan may include fixtures that are available for merchandising and may indicate areas of the store that cannot be merchandised. The structural plan may also include other merchandising properties of the store. A user may interact with the user interface 106 to make merchandising placements for the displayed store layout. Upon receiving such placements, the user interface generation 122 may communicate with merchandising plan generation 124 to validate the placements and check for any errors. Where placement errors are present, the user interface generation 122 may generate a notification to be displayed to the user through user interface 106 to notify the user of possible errors in the placements. In some examples, the user interface generation 122 may also generate an alert to the user where changes to the floor plan of the store have resulted in an update to the store layout that would require new or updated merchandise placement.

In various examples, the memory 116 may include instructions for merchandising plan generation 124. Instructions for merchandising plan generation 124 may, when executed by the processor 114, validate user merchandise placements in a store layout and generate a corresponding merchandising plan. Merchandising plan generation 124 may communicate with user interface generation 122 and user interface 106 to receive user merchandise placements in a store layout. The merchandising plan generation 124 may then validate the user placements relative to the store layout and merchandising categories. For example, the merchandising plan generation 124 may evaluate whether the selected merchandise can fit within the corresponding selected fixture. The merchandising plan generation 124 may also determine if there are any merchandise or merchandise categories that have not been selected for placement in the store or if there are merchandise categories that have been selected for placement, but are not available for placement in the corresponding store. Where there are improper placements, the merchandising plan generation 124 may communicate with the user interface generation 122 to generate a notification to the user to correct the placement.

After validation of user placements, merchandising plan generation 124 may generate a merchandising plan. In some examples, the merchandising plan includes a store layout and merchandising placement data corresponding to the store layout. Merchandising placement data may include the location and position of placed merchandise or merchandise categories in the store and adjacency data relative to the merchandise categories. In some examples, fixtures may be further divided into segments and the merchandising plan may denote the position of merchandise within a segment.

The components shown in FIG. 1 are exemplary only. In various examples, the merchandising module 102 may communicate with and/or include additional components and/or functionality not shown in FIG. 1. For example, the merchandising module 102 may include separate components for communication with digital model generation services.

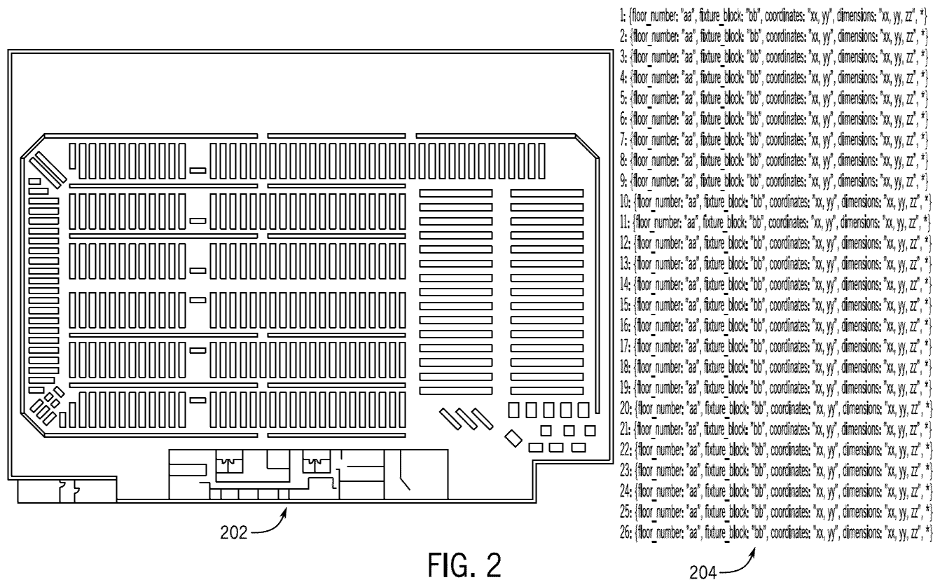

FIG. 2 portrays an example representation of a digital model of a retail store floor plan and a corresponding representation of the digital model in data object format. Image 202 portrays an example representation of a digital model of a retail store. The digital model may be generated using any digital modeling software or systems and may be formatted in any digital model file type, such as for example, CAD or Revit. In some examples, as shown in image 202, the digital model may provide a top-down two-dimensional model of the store and fixtures. In other examples, the digital model may provide a three-dimensional model of the store and fixtures. In the example image 202, fixtures, such as racks, walls, and gondolas, are portrayed in the model to-scale in relationship to the store and portrayed in position corresponding to the actual position of the fixture within the store. In some examples, different labels, shapes, or colors may be used to denote different types of fixtures within the model. A digital model of a store floor plan, such as in example 202, may be received by store model translation 118 for conversion into data object format.

Image 204 portrays an example representation of the store model in data object format. The representation may be generated by store model translation 118 and may reflect the fixtures and data portrayed in a digital model of a retail store. The representation may use any data object format, such as for example, JSON. The data objects may represent individual fixtures portrayed in the digital model and may include size, location, and merchandising properties of the fixtures. For example, the data object may designate the Cartesian coordinates of the fixture, the size and capacity dimensions of the fixture, segments within the fixture, and any merchandising restrictions for the fixture. In some examples, such as example 204, fixture data is represented as key-value pairs.

The example portrayals in FIG. 2 are exemplary only. In various examples digital model and data object representations may include different representations not shown in FIG. 2. For example, data objects may represent fixture data in an array or hash-table instead of in key-value pairs.

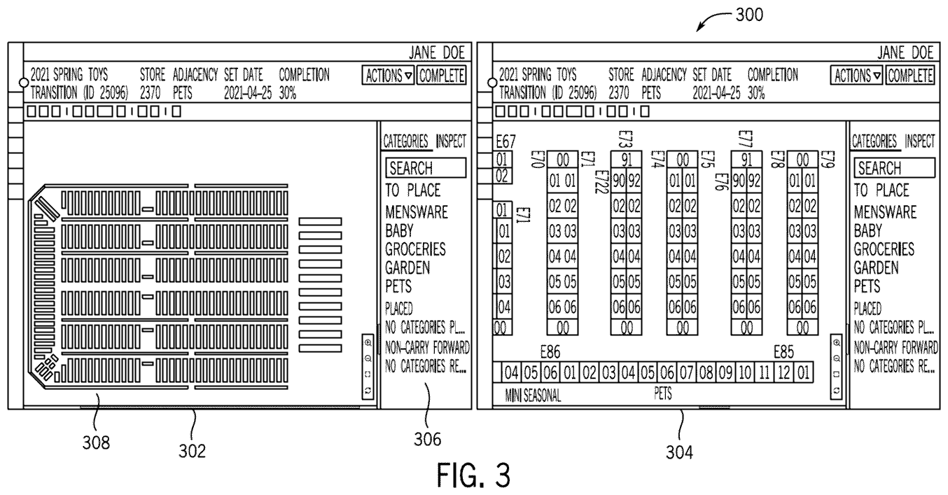

FIG. 3 illustrates an example user interface 300 showing a representation of a store layout. The user interface 300 may be formatted by user interface generation 122 responsive to a request to view the store layout or generate a merchandising plan received from a user device 104 or enterprise system 112. Example image 302 shows the user interface portrayal of structural plan 308, while example image 304 shows the user interface portrayal of a magnified portion of the store layout. Fixtures may be portrayed in position and with size and shape corresponding to the position, size, and shape of the fixture within the store layout. In some examples, fixtures and segments within the fixture may be designated by labels, color-coding, or borders. For example, in image 304, the fixture “E85” is divided into twelve segments labeled “01” through “12.” In some examples, different departments, adjacencies, and merchandise categories may be designated by labels, color-coding, or borders. For example, in image 304, a “Pets” label and color-coding designates the department.

The user interface 300 may include element 306 which may be used to display merchandise and/or merchandise categories and may be used to select merchandise and/or merchandise categories for placement. Such element may be or include, for example, a list panel, drop down menu, or free form text boxes to perform searches, and the like. For example, element 306 is a list of merchandise categories. Users may also use the search text box to search for merchandise categories. Users may drag and drop categories from element 306 to the desired fixture in order to place the merchandise, or click on a fixture to assign a desired merchandise category. In some examples, element 306 may include filters to allow the user to view only selected portions of the merchandise categories. In some examples, element 306 may be configured to display a list of available merchandise instead of merchandise categories. User merchandising placements made from user interface 300 may be communicated with merchandise plan generation 124 for validation and generation of a merchandising plan.

The example user interface in FIG. 3 is exemplary only. In various examples, the user interface may include different representations or functionality not shown in FIG. 3. For example, users may place merchandise categories by clicking on individual fixture segments to assign the merchandise category.

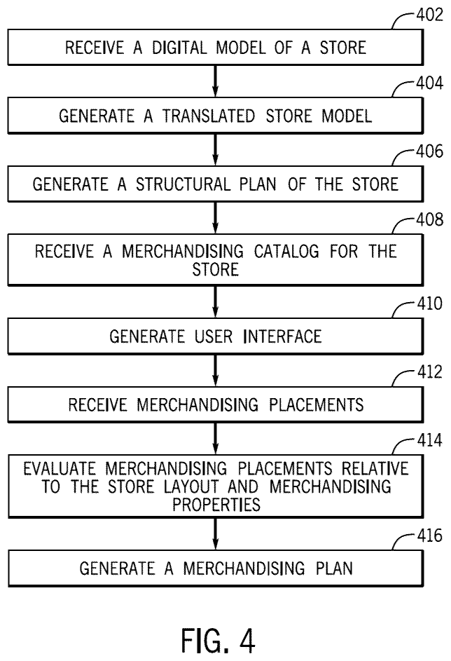

FIG. 4 is a flow diagram of example operations for generating a merchandising plan for a store, such as by using the merchandising module 102. At block 402, the merchandising module 102 receives or accesses a digital model of the floor plan of the store. For example, image 202 from FIG. 2 represents an example digital model received by the merchandising module 102. The digital model may be received from a user device 104, data store 110, or other systems, such as a digital modeling system. For example, a user may transmit a digital model to the merchandising module 102 from a user device 104, or the merchandising module 102 may access a digital model stored in a data store 110. The digital model represents a to-scale model of the one or more floor plans of the store and includes models of one or more fixtures for merchandise placement. The fixture models' size, shape, and placement are to-scale and represent the size, shape, and placement of the corresponding fixture in the store. Digital models may be received through communication from a user device 104, data store 110, enterprise system 112, or other systems, such as a digital modeling system.

At block 404, the merchandising module 102 generates a translated store model, where the translated store model contains one or more data objects including objects that are representative of the different structural and/or architectural features of the store relevant to merchandising. In some examples, merchandising module 102 generates translated store models according to store model translation 118. For example, image 204 from FIG. 2 represents an example translated store model generated from a digital model by merchandising module 102. The merchandising module 102 analyzes the digital model and generates a set of structural objects, e.g., data objects representative of the merchandising fixtures portrayed by the digital model. In creating the translated store model, the merchandising module 102 may disregard certain features of the digital model relevant for engineering purposes but not for merchandising purposes. For example, the translated store model may contain data object representations of fixtures portrayed in the digital model, including data regarding the size, shape, and position of the fixtures and may exclude engineering features of the store, such as the size and positon of windows. The data objects may also contain data representations of merchandising properties of the fixtures, such as the merchandising capacity or number of segments, and/or the merchandising properties of the store, such as the size and dimensions of the store or total merchandising capacity. The data objects representing the store layout may be recorded in store data 120.

At block 406, the merchandising module 102 generates a structural plan of the store. In some examples, the structural plan is generated according to user interface generation 122. For example, element 308 from FIG. 3 portrays a structural plan. The structural plan includes merchandising fixtures and properties and may be displayed through user interface 106. In some examples, the structural plan may only include store features relevant to merchandising and may exclude store features which are only relevant to engineering. For example, the structural plan may include store department designations and the type, position, and merchandising capacity of merchandising fixtures in the store. The merchandising module 102 may generate the structural plan from the translated store model. For example, the merchandising module 102 may use the data objects from the translated store model to place fixtures in the structural plan at the appropriate coordinates and with the appropriate size and shape. In some examples, the structural plan may be rendered as a two dimensional model of the store and fixtures. The structural plan may be stored in store data 120.

At block 408, the merchandising module 102 receives a merchandising catalog for the store. The merchandising catalog may be received through communication from a user device 104, data store 110, enterprise system 112, or other such systems. The merchandising catalog may include merchandising categories available for placement at the store, placement constraints (e.g., the size and dimensions required for placement of merchandising categories, the size and dimensions of merchandise available for placement, and location requirements for sections or departments of the store), and any other properties related to the merchandising space, such as, for example, constraints regarding what merchandising categories may be placed adjacent to each other. For example, merchandising categories may include categories of merchandise such as “pet food” and merchandising properties may include the list of total categories available for placement in the store.

At block 410, the merchandising module 102 generates a user interface. In some examples, the user interface is generated according to user interface generation 122. For example, element 300 of FIG. 3 illustrates an example of a user interface. The merchandising module 102 generates the user interface based on the structural plan generated at block 406 and the merchandising catalog received at block 408. For example, the user interface may include a display of the structural plan including fixtures available for product placement, a display of merchandise or merchandise categories available for placement at the store, a method to select and place merchandise within the structural plan, and an alert system to notify the user of improper merchandising placements or updates to the store layout. For example, the user interface 300 may include a window illustrating the structural plan, including a representation of the store layout, a user-selectable list of merchandising categories, and a pop-up alert system configured to generate notifications to the user.

At block 412, the merchandising module 102 receives merchandising placement selections. The merchandising placements may be received through communication from a user device 104, data store 110, enterprise system 112, or other such systems. In some examples, the merchandising placements may be input by a user via the user interface 300. The user placements may designate placement of merchandise or merchandise categories within the store layout. For example, users may select from a list of merchandise categories displayed on element 306 of user interface 300 and designate placement, e.g., through drag and drop, within the structural plan 308. In other examples, the merchandising placements may be implemented automatically without user input. For example, the merchandising module 102 may generate merchandising placements according to a template received from an enterprise system 112.

At block 414, the merchandising module 102 evaluates the merchandising placements relative to the store layout and merchandising properties. In some examples, the merchandising module 102 may determine whether merchandise and/or merchandise category placements are valid relative to the structural plan. The merchandising module 102 determines that a merchandising placement is valid if the placement satisfies store layout and merchandising constraints. For example, a merchandising placement may be valid where the merchandising module 102 the size of the placed merchandise fits within the capacity of the merchandising fixture and the placement is permissible in light of adjacent placed merchandise categories. Similarly, the merchandising module 102 determines that a merchandising placement is invalid if the placement does not satisfy store layout and merchandising constraints. For example, the merchandising module 102 may determine that a merchandising placement is invalid where the dimensions of the placed merchandise category exceed the capacity of the merchandising fixture, where the placed merchandise category is not available for the store, or where the placed merchandise category violates adjacency restrictions for nearby placed merchandise categories. The merchandising module 102 may also determine that a set of merchandising placements is invalid where the merchandising placements do not complete the total required placements for a store. For example, where the merchandising properties require that all fixtures in a store receive merchandising placement, a set of merchandising placements which leaves some fixtures without placement is invalid.

In some examples, where the merchandising module 102 determines that one or more merchandising placements are invalid, the merchandising module 102 may generate an alert displayed to the user on user interface 300 notifying the user that the one or more merchandising placements are invalid and/or requiring the user to remedy the error. In some examples, the merchandising module 102 may not proceed to block 416 to generate a merchandising plan where at least one merchandising placement remains invalid.

At block 416, the merchandising module 102 generates a merchandising plan based on the merchandising placements. In some examples, a merchandising plan may include a structural plan and one or more valid merchandise and/or merchandise category placements relative to the store layout. The merchandising plan may be generated as a document, such as a PDF or image document. The merchandising module 102 may communicate the merchandising plan to one or more of user devices 104, data stores 110, enterprise systems 112, and other such systems. For example, the merchandising plan may represent the designated merchandising placements for a retail store in a PDF document, and may be communicated to user devices of local administrators at the retail store. The merchandising plan may be recorded in the store data 120.

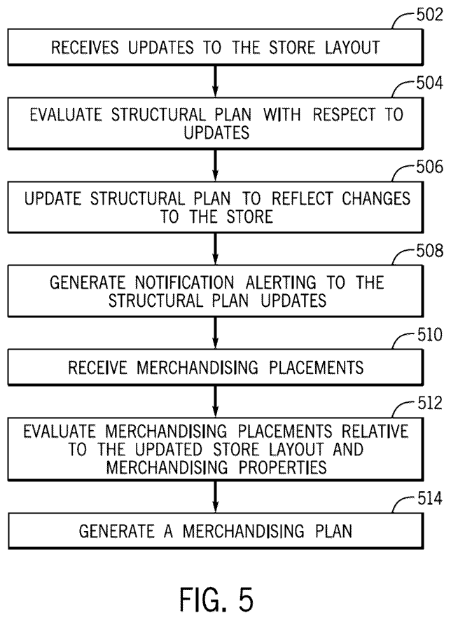

FIG. 5 is a flow diagram of example operations for updating the merchandising plan of a store based on changes to the store layout. Where a store undergoes remodeling, changes the placement of fixtures, and/or updates adjacencies or merchandising categories, the existing structural plan may no longer reflect an accurate layout of the store, and the original merchandising plan generated at block 416 of FIG. 4 may no longer be applicable to the store. As such, the merchandising module 102 may carry out operations to update the structural plan and generate an updated merchandising plan to reflect the changes to the store layout.

At block 502, the merchandising module 102 monitors for and receives updates to the store layout. The merchandising module 102 may be in communication with one or more user devices 104, data stores 110, enterprise systems 112, or other such systems to receive updates reflecting the changes to the floor layout. In some examples, the updates to the store layout may be represented by a digital model. The digital model may include updated information regarding the size and shape of the store, the number, size, shape, and position of fixtures within the store, and/or other merchandising properties of the store, such as areas of the store unavailable for merchandise placement. For example, a retail store may change the position of merchandising for a seasonal sale. The changed positions may be documented in a digital model which depicts all or a portion of the retail store with the updated merchandising fixture positions. The updated digital model may then be a data store 110 or enterprise system 112. The merchandising module 102 may then communicate with the data store 110 or enterprise system 112 to receive the updated digital model.

At block 504, the merchandising module 102 evaluates the existing structural plan with respect to the updated store layout. In some examples, the merchandising module may identify whether discrepancies exist between the current store layout or data object representation and the updated digital model of the store. For example, discrepancies may exist where there are new, removed, or relocated fixtures in the updated digital model which are not reflected in the existing structural plan, or where there are one or more sections of the store designated for seasonal merchandise categories which were not designated as such in the existing structural plan. For example, the merchandising module 102 may identify discrepancies by translating the updated digital model received at block 502 into an updated store model. The updated store model may be translated according to store model translation 118 and may include data objects representing the updated merchandising fixtures. The merchandising module 102 may then compare the updated data objects with the data objects from the existing store model to determine whether any discrepancies exist. For example, where the positional coordinates for a merchandising fixture differs between the existing store model and updated store model, the merchandising module 102 may determine that a discrepancy in the position of the fixture exists. Where discrepancies exist, the merchandising module 102 may record the changes to the store layout in store data 120.

At block 506, the merchandising module 102 updates the structural plan to reflect the changes to the store layout. In some examples, the merchandising module 102 may update the data object representations of the store recorded in store data 120 to reflect the changes to the store layout. For example, if a fixture has been moved from a first location to a second location in the store, the merchandising module 102 may update the data object representing the fixture to reflect its changed location. In some examples, the merchandising module 102 may update the structural plan by translating all or part of the updated digital model into data objects according to store model translation 118. The updated data objects may replace all or part of the existing data objects representing the existing store layout in store data 120. The merchandising module 102 may then update all or part of the existing store layout by generating all or part of a structural plan from the updated data object representation to reflect the changes to the store. The merchandising module may generate the updated structural plan according to user interface generation 122 and the updated structural plan may be displayed within a user interface 300. The updated structural plan reflects the updates to the store received at block 502.

At block 508, the merchandising module 102 generates a notification alerting users to the updates to the store layout. In some examples, the notification may be communicated to one or more user devices 104 and displayed to the user via user interface 300. The notification may be presented as a pop-up within user interface 300 or communicated to the user by other means, such as through email or messaging systems. In some examples, the notification may request or require users to update or make new merchandising placements via user interface 300 which reflect the updated store layout. In some examples, the notification may outline sections of fixtures within the structural plan which require updated merchandising placement.

At block 510, the merchandising module 102 receives user merchandising placements responsive to the changes to the updated structural plan. The merchandising placements may be received through communication from a user device 104, data store 110, enterprise system 112, or other such systems. In some examples, the merchandising placements may be input via the user interface 300. The merchandising placements may designate placement of merchandise or merchandise categories within the store layout. For example, the structural plan 308 may be populated with merchandising placements from the merchandising plan which are still applicable despite the update to the store layout. The user or users may then select from a list of merchandise categories displayed on element 306 of user interface 300 and designate placement, e.g., through drag and drop, within the structural plan 308, either replacing previous merchandising placements or making new placements where needed.

At block 512, the merchandising module 102 evaluates the merchandising placements relative to the updated store layout and merchandising properties. In some examples, the merchandising module 102 may determine whether merchandise and/or merchandise category placements are valid relative to the updated store layout. For example, the merchandising module 102 may determine that a merchandising placement is invalid where the dimensions of the placed merchandise category exceed the dimensions of the fixture capacity. In some examples, the merchandising module 102 may determine whether merchandise and/or merchandise category placements are valid relative to the updated merchandising properties. For example, the merchandising module 102 may determine that a merchandising placement is invalid where the user places a merchandising category that is not available for the store. In another example, the merchandising module 102 may determine that a merchandising placement is invalid where a fixture has been moved to a new department in the updated store layout and the user has not placed merchandise on the fixture which reflects merchandising categories available for the new department. The merchandising module 102 may also determine that a set of merchandising placements is invalid where the merchandising placements do not complete the total required placements for a store. For example, where new fixtures are placed in a store, a set of merchandising placements which leaves some new fixtures without placement is invalid. The merchandising module 102 may also determine that a set of merchandising placements is invalid where the merchandising placements do not include seasonal merchandising categories required for the store. For example, where an update to the store layout designates a section of the store for seasonal merchandising categories, merchandising placements within that may be invalid if they do not conform to the required merchandising categories.

In some examples, where the merchandising module 102 determines that one or more user placements are invalid, the merchandising module 102 may generate an alert displayed to the user on user interface 300 notifying the user that the one or more user placements are invalid and/or requiring the user to remedy the error. In some examples, the merchandising module 102 may not proceed to block 514 to generate an updated merchandising plan where at least one user placement remains invalid.

At block 514, the merchandising module 102 generates a merchandising plan responsive to the changes to the store layout and the updated user placements. In some examples, a merchandising plan may include a representation of the updated store layout and one or more valid merchandise and/or merchandise category placements relative to the store layout. The merchandising module 102 may communicate the merchandising plan to one or more of user devices 104, data stores 110, enterprise systems 112, and other such systems. For example, the merchandising plan may represent updated designated merchandising placements for a retail store and may be communicated to user devices of local administrators at the retail store. The updated merchandising plan may be recorded in store layout 120.

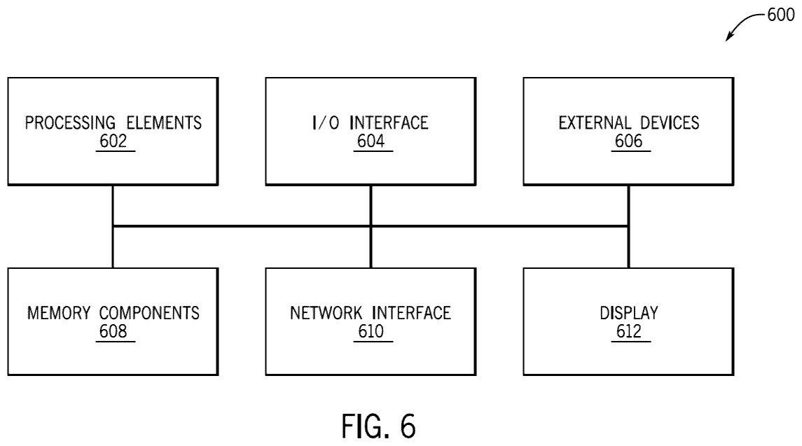

FIG. 6 is a schematic diagram of an example computing system 600 which may be used to implement various embodiments in the examples described herein. For example, processor 114 and memory 116 may be located at one or several computing systems 600. In various embodiments, user devices 104 are also implemented by a computing system 600. This disclosure contemplates any suitable number of computer systems 600. For example, the computing system 600 may be a server, a desktop computing system, a mainframe, a mesh of computing systems, a laptop or notebook computing system, a tablet computing system, an embedded computer system, a system-on-chip, a single-board computing system, or a combination of two or more of these. Where appropriate, the computing system 600 may include one or more computing systems; be unitary or distributed; span multiple locations; span multiple machines; span multiple data centers; or reside in a cloud, which may include one or more cloud components in one or more networks. The computing system 600 may include one or more processing elements 602, an input/output (I/O) interface 604, one or more external devices 606, one or more memory components 608, and a network interface 610. Each of the various components may be in communication with one another through one or more buses or communication networks, such as wired or wireless networks.

The processing element 602 may be any type of electronic device capable of processing, receiving, and/or transmitting instructions. For example, the processing element 602 may be a central processing unit, microprocessor, processor, or microcontroller. Additionally, it should be noted that some components of the computing system 600 may be controlled by a first processor and other components may be controlled by a second processor, where the first and second processors may or may not be in communication with each other.

The I/O interface 604 allows a user to enter data in to computing system 600, as well as provides an input/output for the computing system 600 to communicate with other devices or services. The I/O interface 604 can include one or more input buttons, touch pads, and so on.

The external devices 606 are one or more devices that can be used to provide various inputs to the computing device 600, e.g., mouse, microphone, keyboard, trackpad, or the like. The external devices 606 may be local or remote and may vary as desired. In some examples, the external devices 606 may also include one or more additional sensors.

The memory components 608 are used by the computing system 600 to store instructions for the processing element 602, as well as store data, such as store data 120 (FIG. 1) and the like. The memory components 608 may be, for example, magneto-optical storage, read-only memory, random access memory, erasable programmable memory, flash memory, or a combination of one or more types of memory components.

The network interface 610 provides communication to and from the computing system 600 to other devices. The network interface 610 includes one or more communication protocols, such as, but not limited to WiFi, Ethernet, Bluetooth, and so on. The network interface 610 may also include one or more hardwired components, such as a Universal Serial Bus (USB) cable, or the like. The configuration of the network interface 610 depends on the types of communication desired and may be modified to communicate via Wifi, Bluetooth, and so on.

The display 612 provides a visual output for the computing devices and may be varied as needed based on the device. The display 612 may be configured to provide visual feedback to the user and may include a liquid crystal display screen, light emitting diode screen, plasma screen, or the like. In some examples, the display 612 may be configured to act as an input element for the user through touch feedback or the like.

The components in FIG. 6 are exemplary only. In various examples, the computing system 600 may include additional components and/or functionality not shown in FIG. 6.

Accordingly, the merchandising module 102 described herein addresses particular challenges and needs presented by the merchandising process of retail stores. For example, merchandising a retail store traditionally requires manually creating a representation of the store layout, placing merchandise and/or merchandising categories within the store layout, and/or evaluating the placements. Such manual processes may be time and resource intensive, especially where multiple store locations require merchandising. The merchandising module 102 may automatically generate a structural plan, provide a user interface for simple merchandising placement, and automatically validate user merchandising placements. The merchandising module 102 accordingly provides for an improved merchandising process, reducing the time and resources required to generate a merchandising plan.

The technology described herein may be implemented as logical operations and/or modules in one or more systems. The logical operations may be implemented as a sequence of processor-implemented steps directed by software programs executing in one or more computer systems and as interconnected machine or circuit modules within one or more computer systems, or as a combination of both. Likewise, the descriptions of various component modules may be provided in terms of operations executed or effected by the modules. The resulting implementation is a matter of choice, dependent on the performance requirements of the underlying system implementing the described technology. Accordingly, the logical operations making up the embodiments of the technology described herein are referred to variously as operations, steps, objects, or modules. Furthermore, it should be understood that logical operations may be performed in any order, unless explicitly claimed otherwise or a specific order is inherently necessitated by the claim language.

In some implementations, articles of manufacture are provided as computer program products that cause the instantiation of operations on a computer system to implement the procedural operations. One implementation of a computer program product provides a non-transitory computer program storage medium readable by a computer system and encoding a computer program. It should further be understood that the described technology may be employed in special purpose devices independent of a personal computer.

The above specification, examples and data provide a complete description of the structure and use of exemplary embodiments of the invention as defined in the claims. Although various embodiments of the claimed invention have been described above with a certain degree of particularity, or with reference to one or more individual embodiments, it is appreciated that numerous alterations to the disclosed embodiments without departing from the spirit or scope of the claimed invention may be possible. Other embodiments are therefore contemplated. It is intended that all matter contained in the above description and shown in the accompanying drawings shall be interpreted as illustrative only of particular embodiments and not limiting. Changes in detail or structure may be made without departing from the basic elements of the invention as defined in the following claims.

1. A computer implemented method for merchandising a store comprising:
generating, by a processing element, a data object representation of the store from a digital model of the store;
rendering, by the processing element, a structural plan of the store from the data object representation of the store;
receiving, by the processing element, a merchandising placement specifying a placement of a first merchandising category at a first position within the structural plan
generating by the processing element, a merchandising plan including the first merchandising category positioned at the first position, wherein the first position is related to a location in the store; and
outputting, by the processing element to a display, the merchandising plan.

2. The method of claim 1, wherein generating a merchandising plan further comprises:
evaluating the first position placement relative to structural plan and merchandising properties;
if the first position is valid in relation to the store layout and merchandising properties, generating a merchandising plan including the first merchandising category in the first position, wherein the first position is related to a location in the store; and
if the first position is not valid in relation to the store layout and merchandising properties, generating a notification.

3. The method of claim 1, wherein the data object representation comprises data describing fixtures within the store, including the size, shape, and position of the fixtures.

4. The method of claim 3, wherein the data object representation further comprises data describing fixtures in the store unavailable for merchandising placement.

5. The method of claim 1, wherein merchandising properties comprise a list of merchandising categories available for the store.

6. The method of claim 5, wherein merchandising properties further comprises the size and dimensions required for placement of the merchandising categories.

7. The method of claim 1, further comprising generating a user interface configured to receive user placements, wherein the user interface comprises:
a display of the structural plan;
a display of the store merchandising properties, including merchandising categories available for placement; and
a method to select merchandising categories for placement within the structural plan.

8. The method of claim 1, wherein the first position is valid in relation to the store layout if the first merchandising category fits within the size, shape, position, and capacity of the one or more fixtures of the first position.

9. The method of claim 1, wherein the first position is valid in relation to the merchandising properties if the first merchandising category is included in the one or more merchandising categories available for placement at the first position.

10. The method of claim 1, wherein the merchandising plan includes the structural plan and one or more merchandising category placements within the structural plan.

11. A method for updating a merchandising plan for a store comprising:
evaluating a merchandising plan relative to a digital model of the store;
generating an updated data object representation of the store from the digital model;
rendering an updated structural plan of the store from the updated data object representation of the store;
generating a notification regarding the updated store layout;
receiving a merchandising placement specifying a placement of a first merchandising category at a first position within the updated structural plan;
evaluating the first position placement relative to the updated structural plan and merchandising properties;
if the first position is valid in relation to the store layout and merchandising properties, generating an updated merchandising plan including the first category in the first position, wherein the first position is related to a location in the store; and
if the first position is not valid in relation to the store layout and merchandising properties, generating a notification.

12. The method of claim 11, wherein evaluating the merchandising plan comprises determining if any differences exist in the store layout, fixtures, or merchandising properties between the merchandising plan and the digital model.

13. The method of claim 12, wherein generating an updated data object representation comprises updating an existing data object representation to include the differences in store layout, fixtures, or merchandising properties present in the digital model.

14. The method of claim 13, wherein rendering an updated structural plan comprises generating a structural plan which includes the differences in store layout, fixtures, or merchandising properties present in the digital model.

15. The method of claim 11, wherein the notification regarding the updated store layout prompts or requires a user to make user placements relative to the updated store layout.

16. The method of claim 11, wherein the updated merchandising plan includes the updated structural plan and one or more merchandising category placements within the updated structural plan.

17. A merchandising system comprising:
a store data storage comprising one or more structural plans and merchandising properties; and
a processor configured to generate merchandising plans, wherein the processor is configured to:
generate a data object representation of the store from a digital model of the store;
render a structural plan of the store from the data object representation of the store;
receive a merchandising placement specifying a placement of a first merchandising category at a first position within the structural plan;
generate a merchandising plan including the first merchandising category positioned at the first position, wherein the first position is related to a location in the store; and
output to a display the merchandising plan.

18. The system of claim 17, wherein the processor is further configured to:
evaluate the first position placement relative to structural plan and merchandising properties;
if the first position is valid in relation to the store layout and merchandising properties, generate a merchandising plan including the first category in the first position, wherein the first position is related to a location in the store; and
if the first position is not valid in relation to the store layout and merchandising properties, generate a notification.

19. The system of claim 17, wherein the data object representation comprises representations of fixtures within the store, including the size, shape, and position of the fixtures.

20. The system of claim 17, wherein merchandising properties comprise a list of merchandising categories available for the store.

21. The system of claim 17, wherein the processor is further configured to generate a user interface configured to receive user placement, wherein the user interface comprises:
a display of the structural plan;
a display of the store merchandising properties, including merchandising categories available for placement; and
a method to select merchandising categories for placement within the structural plan.

22. The system of claim 17, wherein the merchandising plan includes the structural plan and one or more merchandising category placements within the structural plan.
